(19) United States
(12) Patent Application Publication
(10) Pub. No.: US 2015/0270315 A1
(43) Pub. Date: Sep. 24, 2015

(54) ORGANIC PHOTOELECTRIC CONVERSION ELEMENT AND IMAGING DEVICE

(71) Applicant: Kabushiki Kaisha Toshiba, Minato-ku (JP)

(72) Inventors: Isao TAKASU, Setagaya (JP); Atsushi WADA, Kawasaki (JP); Yuko NOMURA, Kawasaki (JP); Machiko ITO, Yokohama (JP)

(73) Assignee: Kabushiki Kaisha Toshiba, Minato-ku (JP)

(21) Appl. No.: 14/576,441

(22) Filed: Dec. 19, 2014

(30) Foreign Application Priority Data
Mar. 19, 2014 (JP) 2014-057158
Oct. 21, 2014 (JP) 2014-214445

(51) Int. Cl. H01L 27/30; H01L 51/42

(52) U.S. Cl. CPC H01L 27/307; H01L 51/424

(57) ABSTRACT

According to one embodiment, an organic photoelectric conversion element has a positive electrode, a first charge transport layer, an organic photoelectric conversion, a second charge transport layer and a negative electrode, in this order. The first charge transport layer contains a first charge transport material having a LUMO level equal to or greater than that of the organic photoelectric conversion layer. The second charge transport layer contains a second charge transport material having a HOMO level equal to or less than that of the organic photoelectric conversion layer. The first charge transport layer contains an electron trapping/scattering material that has a HOMO level which is +0.5 eV or more, or −0.5 eV or less, than the HOMO level of the first charge transport material, and has a LUMO level which is between −0.5 eV to +0.5 eV of the LUMO level of the first electron transport material.

### CROSS-REFERENCE TO RELATED APPLICATION

This application is based upon and claims the benefit of priority from Japanese Patent Application No. 2014-57158, filed Mar. 19, 2014 and Japanese Patent Application No. 2014-214445, filed Oct. 21, 2014; the entire contents of which are incorporated herein by reference.

### FIELD

Embodiments described herein relate generally to an organic photoelectric conversion element and an imaging device.

### BACKGROUND

A voltage is frequently applied from the outside to organic photoelectric conversion elements in order to improve photoelectric conversion efficiency and response speed. However, the application of a voltage from the outside ends up causing an increase in dark current due to injection of holes or injection of electrons from the electrodes. Since dark current becomes noise in sensors and the like, there has been a problem of dark current causing a decrease in sensitivity of organic photoelectric conversion elements. Therefore, various studies have been conducted to suppress dark current.

### BRIEF DESCRIPTION OF THE DRAWINGS

FIG. 1 is a drawing showing a cross-section of an organic photoelectric conversion element of a first embodiment.

FIG. 2 is a drawing schematically showing the energy levels of an organic photoelectric conversion element of a first embodiment.

FIG. 3 is a drawing schematically showing a state in which a carrier (electron or hole) propagates through an organic layer.

FIG. 4 is a drawing schematically showing the energy levels of an organic photoelectric conversion element of a second embodiment.

FIG. 5 is a drawing schematically showing the energy levels of an organic photoelectric conversion element of a third embodiment.

FIG. 6 is a drawing schematically showing an imaging device of a fourth embodiment.

### DETAILED DESCRIPTION

Various Embodiments will be described hereinafter with reference to the accompanying drawings.

According to one embodiment, an organic photoelectric conversion element has a positive electrode, a negative electrode, an organic photoelectric conversion layer, a first charge transport layer and a second charge transport layer. The organic photoelectric conversion layer is provided between the positive electrode and the negative electrode. The first charge transport layer is provided between the positive electrode and the organic photoelectric conversion layer, and the first charge transport layer has, as a constituent material of the layer, a first charge transport material that has a LUMO level equal to or greater than the LUMO level of the organic photoelectric conversion layer. The second charge transport layer is provided between the negative electrode and the organic photoelectric conversion layer, and the second charge transport layer has, as a constituent material of the layer, a second charge transport material that has a HOMO level equal to or less than that of the organic photoelectric conversion layer. The first charge transport layer contains an electron trapping/scattering material. The electron trapping/scattering material has a HOMO level which is +0.5 eV or more, or −0.5 eV or less, than the HOMO level of the first charge transport material, and has a LUMO level which is between −0.5 eV to +0.5 eV of the LUMO level of the first electron transport material.

The following provides an explanation of the organic photoelectric conversion element of the present embodiment with reference to the drawings.

### First Embodiment

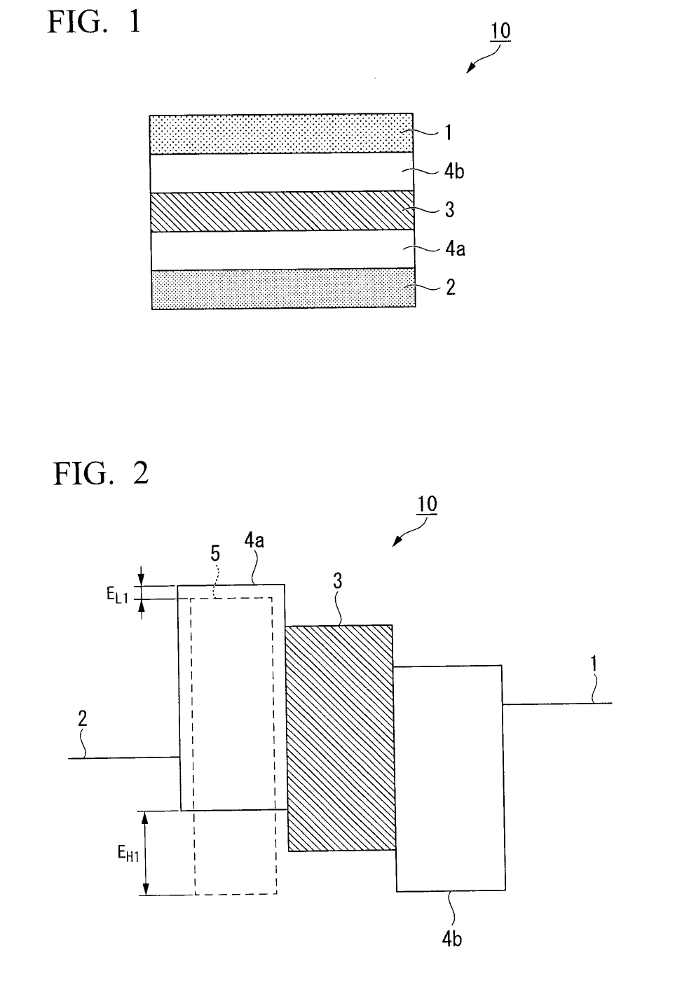

FIG. 1 is a drawing showing a cross-section of an organic photoelectric conversion element 10 of a first embodiment.

An organic photoelectric conversion element 10 has an organic photoelectric conversion layer 3 which is provided between a negative electrode 1 and a positive electrode 2, a first charge transport layer 4a which is provided between the positive electrode 2 and the organic photoelectric conversion layer 3, and a second charge transport layer 4b which is provided between the negative electrode 1 and the organic photoelectric conversion layer 3.

A first charge transport material which is a constituent material of the first charge transport layer 4a has hole transportability that enables it to extract holes generated in the organic photoelectric conversion layer 3 to the positive electrode 2. A second charge transport material which is a constituent material of the second charge transport layer 4b has electron transportability that enables it to extract electrons generated in the organic photoelectric conversion layer 3 to the negative electrode 1. The first charge transport layer 4a contains the first charge transport material and an electron trapping/scattering material. The electron trapping/scattering material traps and/or scatters electrons transported through the first charge transport layer 4a.

A HOMO level of the electron trapping/scattering material is a level which is +0.5 eV or more, or −0.5 eV or less, than the HOMO level of the first charge transport material, and a LUMO level of the electron trapping/scattering material is a level which is +0.5 eV or less, or −0.5 eV or more, than the LUMO level of the first charge transport material.

Furthermore, in the case there is only one type of molecule that composes the organic photoelectric conversion layer, the LUMO level and HOMO level of the organic photoelectric conversion layer respectively refer to the LUMO level and HOMO level of that molecule. In the case the organic photoelectric conversion layer is composed of two or more types of molecules, the LUMO level and HOMO level of the organic photoelectric conversion layer refer to the lowest LUMO level and highest HOMO level among constituent molecules thereof.

FIG. 2 is a drawing schematically showing the energy levels of the organic photoelectric conversion element 10 of a first embodiment. In FIG. 2, energy levels when the principal energy level of the first charge transport layer 4a is attributable to the first charge transport material are indicated as a typical case thereof. Since the amount of electron trapping/scattering material in the first charge transport layer 4a is low and there are little effects thereof, the energy level thereof can be ignored. The energy level of the first charge transport layer 4a is nearly equal to the energy level of the first charge transport material.

The first charge transport material has a LUMO level that is equal to or greater than the LUMO level of the organic photoelectric conversion layer 3. The LUMO level of the first charge transport material is preferably higher than the LUMO level of the organic photoelectric conversion layer 3 and is more preferably at least 0.5 eV higher. The energy level of the positive electrode 2 is preferably at least 1.3 eV lower than the energy of the LUMO level of the first charge transport material.

If the LUMO level of the first charge transport material is higher than the LUMO level of the organic photoelectric conversion layer 3, electrons of the positive electrode 2 can be blocked from flowing to the side of the negative electrode 1 as dark current. The reason is that, if electrons of the positive electrode 2 are about to flow to the side of the negative electrode 1 (that is, dark current is about to occur), a large amount of energy is required which is larger than energy level difference between the energy level of the positive electrode 2 and the LUMO level of the first charge transport material to enable such a flow.

The HOMO potential of the first charge transport material is preferably equal to or less than the energy level of the positive electrode 2 and equal to or greater than the HOMO level of the organic photoelectric conversion layer 3.

If the HOMO level of the first charge transport material is within this range, holes generated in the organic photoelectric conversion layer 3 are able to flow to the positive electrode 2 without being impeded by the first charge transport layer 4a. Namely, decreases in photoelectric conversion efficiency accompanying insertion of the first charge transport layer 4a can be avoided.

There are no particular limitations on the first charge transport material provided it has the LUMO and HOMO levels described above. The first charge transport material preferably has hole transportability, and a p-type semiconductor material is preferable. More specifically, derivatives and polymers containing quinacridone, thiophene or carbazole and the like are preferable, and the same p-type semiconductors as those used in the organic photoelectric conversion layer 3 to be subsequently described can also be used.

The thickness of the first charge transport layer 4a is preferably 10 nm to 200 nm, more preferably 10 nm to 150 nm, and even more preferably 10 nm to 100 nm. If the first charge transport layer 4a is excessively thin, the dark current suppressing effect thereof decreases, while if it is excessively thick, photoelectric conversion efficiency decreases.

The first charge transport layer 4a also fulfills the role of effectively transporting holes generated in the organic photoelectric conversion layer 3 for extraction to the positive electrode 2, and the first charge transport layer 4a may or may not induce photoelectric conversion.

The second photoelectric conversion layer 4b contains a second charge transport material having a HOMO level equal to or less than the HOMO level of the organic photoelectric conversion layer 3. The HOMO level of the second charge transport material is preferably lower than the HOMO level of the organic photoelectric conversion layer 3 and is more preferably at least 0.5 eV lower. The difference between the energy level of the negative electrode 1 and the HOMO level of the second charge transport material is preferably 1.3 eV or more.

If the HOMO level of the second charge transport material is lower than the HOMO level of the organic photoelectric conversion layer 3, holes of the negative electrode 1 can be blocked from flowing to the side of the positive electrode 2 as dark current. The reason is that, if holes of the negative electrode 1 are about to flow to the side of the positive electrode 2 (that is, dark current is about to occur), a large amount of energy is required which is larger than energy level difference between the energy level of the negative electrode 1 and the HOMO level of the second charge transport material to enable such a flow.

The LUMO level of the second charge transport material is preferably equal to or greater than the energy level of the negative electrode 1 and equal to or less than the LUMO level of the organic photoelectric conversion layer 3. If the LUMO level of the second charge transport material is within this range, electrons generated in the organic photoelectric conversion layer 3 are able to flow to the negative electrode 1 without being impeded. Namely, decreases in photoelectric conversion efficiency accompanying insertion of the second charge transport layer 4b can be avoided.

There are no particular limitations on the second charge transport material provided it has the previously described LUMO and HOMO levels. The second charge transport material preferably has electron transportability and is preferably an n-type semiconductor material. More specifically, perylene derivatives, naphthalene derivatives, thiophene derivatives, fullerene derivatives and metal complex compounds (such as aluminum complexes wherein examples thereof include Alq3 (tris(8-hydroxyquinolinato)aluminum)) are preferable, and the same n-type semiconductors as those used in the organic photoelectric conversion layer to be subsequently described can also be used.

The thickness of the second charge transport layer 4b is preferably 10 nm to 200 nm, more preferably 10 nm to 150 nm and even more preferably 10 nm to 100 nm. If the second charge transport layer 4b is excessively thin, the dark current suppressing effect thereof decreases, while if it is excessively thick, photoelectric conversion efficiency decreases.

The second charge transport layer 4b also fulfills the role of effectively transporting electrons generated in the organic photoelectric conversion layer 3 for extraction to the negative electrode, and the second charge transport layer 4b may or may not induce photoelectric conversion.

The first charge transport layer 4a has an electron trapping/scattering material 5. The electron trapping/scattering material 5 has a HOMO level which is +0.5 eV or more, or −0.5 eV or less, than the HOMO level of the first charge transport material (that is, the absolute value of the energy level difference E_{H1} is 0.5 eV or more), and has a LUMO level which is between −0.5 eV to +0.5 eV of the LUMO level of the first charge transport material (that is, the absolute value of the energy level difference E_{L1} is 0.5 eV or less). In other words, the HOMO level of the electron trapping/scattering material 5 is at least 0.5 eV lower, or at least 0.5 eV higher, than the HOMO level of the first charge transport material. Furthermore, the LUMO level of the electron trapping/scattering material 5 is equal to or lower than an energy level which is 0.5 eV higher than the LUMO level of the first charge transport material, and is equal to or higher than an energy level which is 0.5 eV lower than the LUMO level of the first charge transport material. It is preferable that the HOMO level of the electron trapping/scattering material 5 be at least 0.7 eV or lower, and more preferably at least 1.0 eV or lower, than the HOMO level of the first charge transport material.

As a result of making the absolute value of the energy level difference E_{L1} between the LUMO level of the first charge transport material and the LUMO level of the electron trapping/scattering material 5 be 0.5 eV or less, electrons which are unable to be completely blocked with the first charge transport material alone can be trapped or scattered within the first charge transport layer 4a. On the other hand, as a result of making the absolute value of the energy level difference E_{H1} between the HOMO level of the first charge transport material and the HOMO level of the electron trapping/scattering material 5 be 0.5 eV or more, holes generated in the organic photoelectric conversion layer 3 are able to flow to the positive electrode 2 without being impeded. Consequently, dark current can be suppressed without lowering photoelectric conversion efficiency.

The following provides an explanation of the principle by which electrons are trapped or scattered in the first charge transport layer 4a due to a difference in energy level.

The conduction of carriers (electrons or holes) in organic materials is typically governed by hopping conduction wherein propagation is caused by hopping to and from HOMO levels or LUMO levels localized in each molecule.

The probability of hopping conduction from a certain occupied state i to an empty state j of a molecule can be expressed in the manner indicated below based on the Miller-Abraham equation.

νᵢⱼ=ν₀e^{-2r}^{ᵢⱼ}^{/α-ΔE/kT}

(ΔE=εⱼ−εᵢ≧0) (a)

wherein, ν₀ represents a value dependent on the strength of the interaction between phonons and electrons, rᵢⱼ represents the distance between an occupied state i and an empty state j, a represents the localization length of the hopping state, k represents the Boltzmann constant and T represents absolute temperature. In addition, εᵢ and εⱼ represent, respectively, the localization energy of state i and state j.

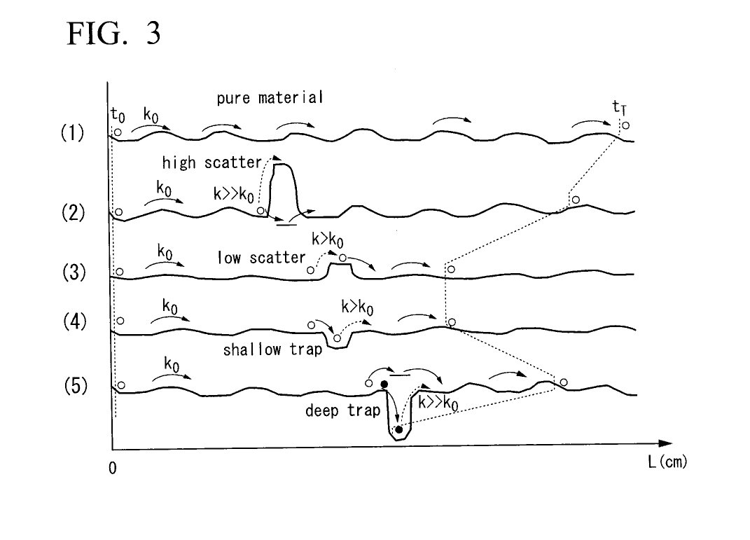

FIG. 3 is a drawing schematically showing the state of a carrier (electron or hole) propagating through an organic layer.

Plot (1) of FIG. 3 schematically indicates the propagating state of a carrier in an organic layer composed of a single material. In plot (1) of FIG. 3, a carrier that has set out at a point after t₀ seconds propagates to a location L cm away after t_{T} seconds. At this time, since the organic layer is composed of a single material, the carrier propagates while being subjected to hardly any trapping or scattering.

On the other hand, plots (3) and (4) of FIG. 3 schematically indicate the propagating states of carriers in the case of adding a material having a slightly different energy level to an organic layer composed of a single material. Plot (3) indicates the case in which a material having a slightly higher energy level is mixed in, while plot (4) indicates the case in which a material having a slightly lower energy level is mixed in.

In the following description, the energy level of the principal organic material is referred to as the host energy level, while the energy level of a material mixed into the organic layer is referred to as the guest energy level.

At this time, the probability of hopping conduction between host energy levels and the probability of hopping conduction from a host energy level to a guest energy level can be determined to not have a large difference therebetween from general formula (a) (since ΔE is small). In other words, hopping from a host energy level to a guest energy level occurs frequently.

On the other hand, since the energy difference between the host energy level and the guest energy level is larger than the energy levels between host energy levels, carrier propagation is impeded when the difference in energy levels is exceeded. Consequently, as shown in plots (3) and (4), the propagatable distance after t_{T} seconds becomes short. That is to say, a carrier can be understood to be trapped and scattered by even a slight difference in energy levels and the propagation thereof is impeded.

In the first embodiment, the electron trapping/scattering material 5 is mixed with the first charge transport material which is the main component of the first charge transport layer. The LUMO level of the electron trapping/scattering material has a slight energy level difference E_{L1} between the LUMO level of the first charge transport material and the LUMO level of the electron trapping/scattering material, wherein the absolute value of the difference being within 0.5 eV.

That is, the LUMO level of the first charge transport material is the host energy level, and the LUMO level of the electron trapping/scattering material 5 is the guest energy level. Therefore, “low scatter” shown in plots (3) in FIG. 3 means the condition that the LUMO level of the electron trapping/scattering material 5 is slightly (0 to 0.5 eV) higher than the LUMO level of the first charge transport material, and “shallow trap” shown in plots (4) in FIG. 3 means the condition that the LUMO level of the electron trapping/scattering material is slightly (0 to 0.5 eV) lower than the LUMO level of the first charge transport material. When the first charge transport material is mixed with the electron trapping/scattering material 5, carriers in the form of electrons are trapped and scattered by the electron trapping/scattering material 5. In other words, as a result of mixing the electron trapping/scattering material 5 into the first charge transport material, electrons that were unable to be completely blocked can be trapped and scattered.

Examples of a combination of the first charge transport material and electron trapping/scattering material include a combination of N,N′-dimethylquinacridone and bis-4,6-(3,5-di-3-pyridylphenyl)-2-methylpyrimidine (B3PYMPM). The LUMO energy level difference E_{L1} in this case is about 0.1 eV and electrons unable to be completely blocked in the first charge transport layer 4a can be trapped. In the case of using N,N′-di(naphthalen-1-yl)-N,N′-diphenyl benzidine (NPB) and (4,4-N,N-dicarbazole)biphenyl (CBP) as the combination, the LUMO energy level difference E_{L1} is about 0.2 eV. In this case as well, electrons unable to be completely blocked in the first charge transport layer 4a can be trapped.

Next, an explanation is provided of the principle by which holes generated in the organic photoelectric conversion layer 3 flow to the positive electrode 2 without being impeded despite having an energy level difference.

Plots (2) and (5) of FIG. 3 indicate carrier propagation states in the case of adding a material having a considerably different energy level into an organic layer composed of a single material. Plot (2) indicates the case of mixing a material having a much higher energy level, while plot (5) indicates the case of mixing a material having much lower energy level.

At this time, the probability of hopping conduction from a host energy level to a guest energy level can be determined from general formula (a) to be such that the probability thereof decreases considerably in comparison with the probability of hopping conduction between host energy levels (since ΔE is large).

Consequently, transition by a carrier to a guest energy level is avoided, while the carrier instead propagates so as to detour to another nearby host energy level. The carrier propagates by detouring in this manner without being trapped or scattered by guest energy levels. Therefore, although the propagatable distance after t_{T} seconds is slightly shorter in comparison with plot (1) as shown in plots (2) and (5), the propagation thereof can be determined to be hardly impeded at all.

In the first embodiment, the electron trapping/scattering material 5 is mixed with the first charge transport material which is the main component of the first charge transport material layer. The HOMO level of the electron trapping/scattering material has the absolute value of a large energy level difference E_{H1} of 0.5 eV or more between the HOMO level of the first charge transport material and the HOMO level of the electron trapping/scattering material. That is, the HOMO level of the first charge transport material is the host energy level, and the HOMO level of the electron trapping/scattering material 5 is the guest energy level. Therefore, “high scatter” shown in plots (2) in FIG. 3 means that the HOMO level of the electron trapping/scattering material 5 is at least 0.5 eV higher than the HOMO level of the first charge transport material, and “shallow trap” shown in plots (5) in FIG. 3 means that the HOMO level of the electron trapping/scattering material 5 is at least 0.5 eV lower than the HOMO level of the first charge transport material. When the first charge transport material is mixed with the electron trapping/scattering material 5, holes propagate between the energy levels of the first charge transport material so as to detour without moving to an energy level of the electron trapping/scattering material 5, holes generated in the organic photoelectric conversion layer 3 are not impeded.

In the case the combination of the first charge transport material and the electron trapping/scattering material 5 is the previously exemplified N,N′-dimethylquinacridone and B3PYMPM, the HOMO energy level difference E_{H1} thereof is about 1.3 eV. Consequently, holes generated in the organic photoelectric conversion layer 3 are able to flow to the positive electrode without being impeded. In the case of using NPB and CBP, the HOMO energy level difference E_{H1} is about 0.6 eV. In this case as well, holes generated in the organic photoelectric conversion layer 3 are able to flow to the positive electrode without being impeded.

There are no particular limitations on the electron trapping/scattering material 5 provided it is a material that has the LUMO and HOMO levels previously described. Examples of materials that can be used include 1,4,5,8-naphthalene tetracarboxylic-dianhydride (NTCDA), 1,3-bis(5-(4-tert-butylphenyl)-1,3,4-oxadiazol-2-yl)benzene (OXD-7), tris-[3-(3-pyridyl)mesityl]borane (3TPYMB) and bis-4,6-(3,5-di-3-pyridylphenyl)-2-methylpyrimidine (B3PYMPM).

The electron trapping/scattering material 5 is preferably contained in the first charge transport layer 4a at a weight ratio of 1% to 50% and may also be contained at a weight ratio of 10% to 40%. Even if outside this range, since an energy level difference exists between the electron trapping/scattering material 5 and the first charge transport material, the effect of trapping and scattering electrons is demonstrated.

However, if the ratio at which the electron trapping/scattering material 5 is contained in the first charge transport layer 4a exceeds a weight ratio of 50%, the electron trapping/scattering material 5 becomes the principal material in the first charge transport layer 4a. In this case, the energy level of the electron trapping/scattering material 5 becomes the host energy level, and hopping between energy levels of the electron trapping/scattering material 5 becomes the principal form of hopping conduction. If the electron trapping/scattering material 5 provides the principle form of hopping conduction, the following problem occurs in the case the LUMO level of the electron trapping/scattering material 5 is lower than the LUMO level of the first electron transport material.

In the case of transition from the positive electrode 2 to the first charge transport layer 4a, if the weight ratio of the electron trapping/scattering material 5 is 50% by weight or less, electrons are mainly blocked by the energy level difference between the energy level of the positive electrode 2 and the LUMO level of the first charge transport material. On the other hand, if the weight ratio of the electron trapping/scattering material 5 exceeds 50% by weight, the electron trapping/scattering material 5 becomes the principal material of the first charge transport layer 4a. Consequently, in the case of transition from the positive electrode 2 to the first charge transport layer 4a, electrons are mainly blocked by the energy level difference between the energy level of the positive electrode 2 and the LUMO level of the electron trapping/scattering material 5. In other words, in the case the LUMO level of the electron trapping/scattering material 5 is lower than the LUMO level of the first charge transport material, the function of blocking electrons from the positive electrode 2 diminishes and the effect of suppressing dark current ends up decreasing.

In contrast, this problem does not occur in the case that the weight ratio of the electron trapping/scattering material 5 is 50% by weight or less, or in the case that the weight ratio of the electron trapping/scattering material 5 is 50% by weight or more and the LUMO level of the electron trapping/scattering material 5 is higher than the LUMO level of the first charge transport material.

The negative electrode 1 and the positive electrode 2 can be selected in consideration of such factors as adhesion with adjacent materials, energy level and stability, and can be preferably selected. For example, a metal, alloy, metal oxide, electrically conductive compound or mixture thereof can be used.

Specific examples of materials that can be used for the electrodes include indium tin oxide (ITO), SnO₂ obtained by adding a dopant, aluminum zinc oxide (AZO) obtained by adding Al as a dopant to ZnO, gallium zinc oxide (GZO) obtained by adding Ga as a dopant to ZnO, and indium zinc oxide (IZO) obtained by adding In as a dopant to ZnO. In addition, materials such as CdO, TiO₂, CdIn₂O₄, InSbO₄, Cd₂SnO₂, Zn₂SnO₄, MgInO₄, CaGaO₄, TiN, ZrN, HfN or LaB₆ can also be used. Examples of electrically conductive polymers that can be used include PEDOT:PSS, polythiophene compounds and polyaniline compounds. Other examples of materials that can be used include nanocarbon materials, such as carbon nanotubes or graphene, and Ag nanowire.

One of the negative electrode 1 and the positive electrode 2 can be composed of a material other than a transparent electrode. In this case, examples of materials that can be used for the electrode include W, Ti, TiN and Al.

A p-type semiconductor single layer, n-type semiconductor single layer, laminated structure which is obtained by laminating a p-type semiconductor layer and n-type semiconductor layer, or a mixed film formed by mixed coating and co-deposition of a p-type semiconductor layer and n-type semiconductor layer, for example, can be used for the organic photoelectric conversion layer 3.

Amine derivatives, quinacridone derivatives, naphthalene derivatives, anthracene derivatives, phenanthracene derivatives, tetracene derivatives, pyrene derivatives, perylene derivatives or fluoranthene derivatives and the like can be used as p-type organic semiconductors and n-type organic semiconductors. In addition, polymers of phenylene and vinylene, fluorene, carbazole, indole, pyrene, pyrrole, picoline, thiophene, acetylene or diacetylene and the like, and derivatives thereof, can also be used. Moreover, dithiol metal complex-based dyes, metal phthalocyanine dyes, metal porphyrin-based dyes, ruthenium complex dyes, cyanine-based dyes, merocyanine-based dyes, phenyl xanthene-based dyes, triphenylmethane-based dyes, rhodacyanine-based dyes, xanthene-based dyes, macrocyclic azaazulene-based dyes, azulene-based dyes, naphthoquinone, anthraquinone-based dyes, linear compounds obtained by condensing a condensed polycyclic aromatic compound such as anthracene or pyrene with an aromatic compound and/or heterocyclic compound, two nitrogen-containing heterocyclic compounds such as quinoline, benzothiazole or benzoxazole having a squarylium group and a croconic methine group as bonding chains, or cyanine-like dyes obtained by bonding a squarylium group and croconic methane group can also be used. In addition, fullerenes such as C60 or C70 and derivatives thereof can be used as n-type semiconductors.

From the viewpoint of photoelectric conversion efficiency, a mixed film wherein a p-type semiconductor and an n-type semiconductor are combined is preferable. In this case, the p-type semiconductor is preferably a derivative or polymer containing an amine, quinacridone, thiophene, carbazole or the like, while the n-type semiconductor is preferably a perylene derivative, naphthalene derivative, thiophene derivative or fullerene derivative.

Each layer of the organic photoelectric conversion element 10 can be fabricated using a dry film forming method or wet film forming method. Specific examples of dry film forming methods include physical vapor deposition methods such as vacuum deposition, sputtering, ion plating, or molecular beam epitaxy (MBE) or chemical vapor deposition (CVD) methods such as plasma polymerization. Examples of wet film forming methods that can be used include coating methods such as casting, spin coating, dipping and the Langmuir-Blodgett (LB) method. Printing methods such as inkjet printing or screen printing, and transfer methods such as thermal transfer or laser transfer may also be used.

The first charge transport layer 4a can be formed by mixing the first charge transport material and the electron trapping/scattering material 5. Although there are no particular limitations on the mixing method, a commonly used physical mixing method may be used. For example, in the case of dry film formation method, the first charge transport layer 4a can be formed by vacuum deposition of the materials. In the case of wet film formation method, the materials can be added to a solvent so that the materials are used for the method.

### Second Embodiment

According to one embodiment, an organic photoelectric conversion element has a positive electrode, a negative electrode, an organic photoelectric conversion layer, a first charge transport layer and a second charge transport layer. The organic photoelectric conversion layer is provided between the positive electrode and the negative electrode. The first charge transport layer is provided between the positive electrode and the organic photoelectric conversion layer, and has as a constituent material thereof a first charge transport material that has a LUMO level equal to or greater than the LUMO level of the organic photoelectric conversion layer. The second charge transport layer is provided between the negative electrode and the organic photoelectric conversion layer, and has as a constituent material thereof a second charge transport material that has a HOMO level equal to or less than the HOMO level of the organic photoelectric conversion layer. The second charge transport layer contains a hole trapping/scattering material. The hole trapping/scattering material has a HOMO level which is between −0.5 eV to +0.5 eV of the HOMO level of the second charge transport material. The hole trapping/scattering material also has a LUMO level which is +0.5 eV or more, or −0.5 eV or less, than the LUMO level of the second electron transport material.

The following provides an explanation of an organic photoelectric conversion element of a second embodiment with reference to the drawings.

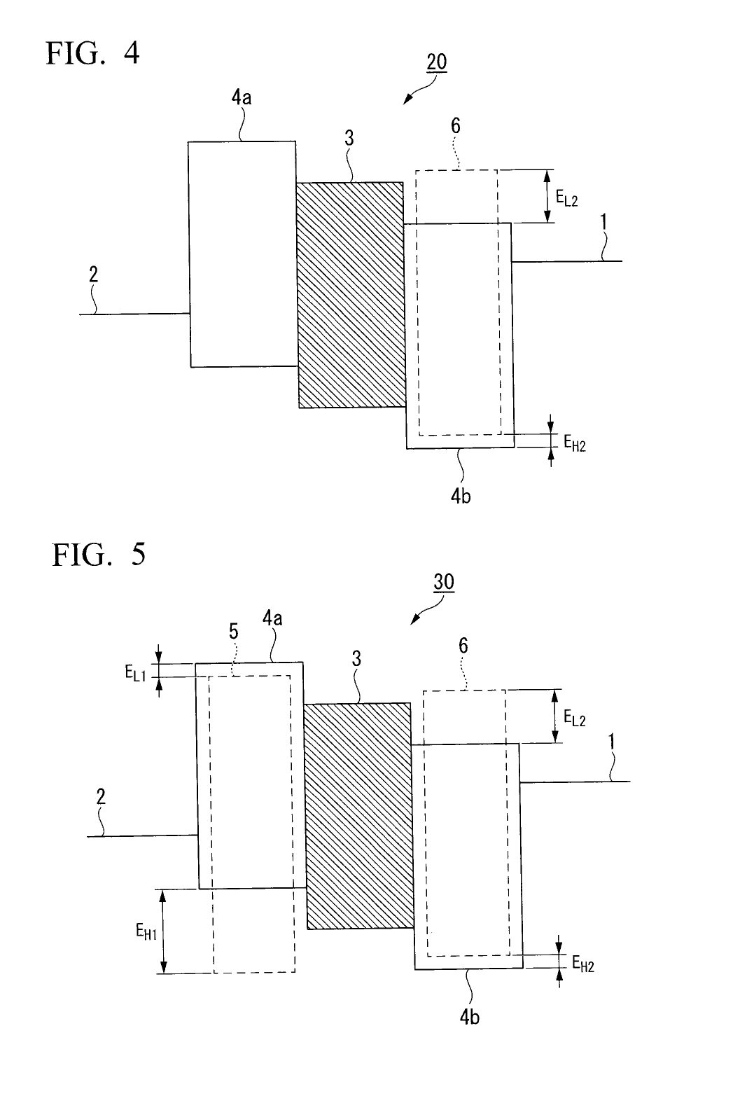

FIG. 4 is a drawing schematically showing the energy levels of an organic photoelectric conversion element 20 of the second embodiment. In FIG. 4, energy levels in the case the principal energy level of the second charge transport layer 4b is attributable to the second charge transport material are indicated as a typical case thereof.

Here, the layer structure of the organic photoelectric conversion element 20 of the second embodiment is the same as that of the organic photoelectric conversion element 10 of the first embodiment (see FIG. 1). That is to say, the organic photoelectric conversion element 20 has the organic photoelectric conversion layer 3 provided between the negative electrode 1 and the positive electrode 2, the first charge transport layer 4a provided between the positive electrode 2 and the organic photoelectric conversion layer 3, and the second charge transport layer 4b provided between the negative electrode 1 and the organic photoelectric conversion layer 3. On the other hand, the organic photoelectric conversion element 20 differs from the organic photoelectric conversion element 10 of the first embodiment in that the first charge transport layer 4a does not have the electron trapping/scattering material 5 and the second charge transport layer 4b has a hole trapping/scattering material 6.

The first charge transport material and the second charge transport material have the same energy levels as in the first embodiment. Consequently, the first charge transport layer 4a and the second charge transport layer 4b are able to block the flow of dark current. In addition, the flow of electrons and holes generated in the organic photoelectric conversion layer is not impeded.

The second charge transport layer 4b of the organic photoelectric conversion element 20 has the hole trapping/scattering material 6. As shown in FIG. 4, the hole trapping/scattering material 6 has a HOMO level which is between −0.5 eV to +0.5 eV of the HOMO level of the second charge transport material (that is, the absolute value of the energy level difference E_{H2} is 0.5 eV or less), and has a LUMO level that is +0.5 eV or more, or −0.5 eV or less, than the LUMO level of the second charge transport material (that is, the absolute value of the energy level difference E_{L2} is 0.5 eV or more). In the other words, the HOMO level of the hole trapping/scattering material is equal to or lower than an energy level which is 0.5 eV higher than the HOMO level of the second charge transport material, and is equal to or higher than an energy level which is 0.5 eV lower than the HOMO level of the second charge transport material. The LUMO level of the hole trapping/scattering material is at least 0.5 eV lower, or at least 0.5 eV higher than the LUMO level of the second charge transport material. The LUMO level of the hole trapping/scattering material 6 preferably has energy level which is at least 0.7 eV higher than the LUMO level of the second charge transport material, and more preferably has energy level which is at least 1.0 eV higher than the LUMO level of the second charge transport material.

As a result of making the absolute value of the energy level difference E_{H2} between the HOMO level of the second charge transport material and the HOMO level of the hole trapping/scattering material 6 be 0.5 eV or less, holes unable to be completely blocked with the second charge transport material alone can be trapped or scattered within the second charge transport layer 4b. On the other hand, as a result of making the absolute value of the energy level difference E_{L2} between the HOMO level of the second charge transport material and the HOMO level of the hole trapping/scattering material 6 be 0.5 eV or more, electrons generated in the organic photoelectric conversion layer 3 are able to flow to the negative electrode 1 without being impeded. Consequently, dark current can be suppressed without lowering photoelectric conversion efficiency.

These principles are the same as the principle of electrons being trapped and scattered due to E_{L1} and the principle of holes flowing to the positive electrode 2 without being impeded due to E_{H1} in the first embodiment.

Examples of a combination of the second charge transport material and the hole trapping/scattering material include a combination of N,N′-bis(2,5-di-tert-butylphenyl)-3,4,9,10-perylene dicarboxamide (PDCDT) and N,N-dicarbazoyl-3,5-benzene (mCP). In the case of this combination, the HOMO energy level difference E_{H2} is about 0.1 eV, and the LUMO energy level difference E_{L2} is about 1.4 eV. Consequently, holes unable to be completely blocked in the second charge transport layer 4b can be trapped and electrons generated in the organic photoelectric conversion layer 3 are not impeded from flowing to the negative electrode.

In the case of using the combination of Alq3 and 4,4′,4″-tris(carbaz;Tris(4-carbazoyl-9-ylphenyl)amine)) (TCTA), the HOMO energy level difference E_{H2} is about 0.2 eV, and the LUMO energy level difference E_{L2} is about 0.9 eV. In this case as well, holes which are unable to be completely blocked in the second charge transport layer 4b can be trapped, and electrons generated in the organic photoelectric conversion layer 3 are not impeded from flowing to the negative electrode.

There are no particular limitations on the hole trapping/scattering material 6 provided it has the LUMO and HOMO levels previously described. Examples of materials that can be used include (4,4-N,N-dicarbazole)biphenyl (CBP), N,N-dicarbazoyl-3,5-benzene (mCP), 4,4′,4″-tris(carbaz;Tris (4-carbazoyl-9-ylphenyl)amine) (TCTA), bis(2-methyl-8-quinolinoato-N1,O8)-1,1′-biphenyl-4-olato)aluminum (BAlq), bathophenanthroline (BPhen) and bathocuproline (BCP).

The hole trapping/scattering material 6 is preferably contained at a weight ratio of 1% to 50% with respect to the second charge transport material and may also be contained at a weight ratio of 10% to 40%. Even if outside this range, since an energy level difference exists between the hole trapping/scattering material 6 and the second charge transport material, the effect of trapping and scattering holes is demonstrated.

However, if the ratio at which the hole trapping/scattering material 6 is contained exceeds 50% by weight, the hole trapping/scattering material 6 becomes the principal material in the second charge transport layer 4b. In this case, the energy level of the hole trapping/scattering material 6 becomes the host energy level, and hopping between energy levels of the hole trapping/scattering material 6 becomes the principal form of hopping conduction. If the hole trapping/scattering material 6 provides the principle form of hopping conduction, the following problem occurs in the case the HOMO level of the hole trapping/scattering material 6 is higher than the HOMO level of the second electron transport material.

If the weight ratio of the hole trapping/scattering material 6 is 50% by weight or less, in the case of transition from the negative electrode 1 to the second charge transport layer 4b, holes are mainly blocked by the energy level difference between the energy level of the negative electrode 1 and the HOMO level of the second charge transport material. On the other hand, if the weight ratio of the hole trapping/scattering material 6 exceeds 50% by weight, the hole trapping/scattering material 6 becomes the principal material of the second charge transport layer 4b. In the case of transition from the negative electrode 1 to the second charge transport layer 4b, holes are mainly blocked by the energy level difference between the energy level of the negative electrode 1 and the HOMO level of the hole trapping/scattering material 6. In other words, in the case the HOMO level of the hole trapping/scattering material 6 is higher than the HOMO level of the second charge transport material, the function of blocking holes from the negative electrode 1 diminishes and the effect of suppressing dark current decreases.

In contrast, this problem does not occur in the case that the weight ratio of the hole trapping/scattering material is 50% by weight or less, or in the case that the weight ratio of the hole trapping/scattering material is 50% by weight or more and the HOMO level of the hole trapping/scattering material 6 is lower than the HOMO level of the second charge transport material.

The negative electrode 1, the positive electrode 2 and the organic photoelectric conversion layer 3 can be selected and used in the same manner as in the first embodiment. The voltage applied to the organic photoelectric conversion layer 3 is also preferably within the same range as in the first embodiment.

The organic photoelectric conversion element 20 can be fabricated using the same method as that of the first embodiment.

The second charge transport layer 4b can be formed by mixing the hole trapping/scattering material 6 into the second charge transport material. Although there are no particular limitations on the mixing method, a commonly used physical mixing method may be used. For example, in the case of dry film forming method, the second charge transport layer 4b can be formed by vacuum deposition of the materials. In the case of wet film forming method, the materials can be added to a solvent so that the materials are used for the method.

### Third Embodiment

The following provides an explanation of an organic photoelectric conversion element of a third embodiment with reference to the drawings.

FIG. 5 is a drawing schematically showing the energy levels of an organic photoelectric conversion element 30 of the third embodiment. In FIG. 5, energy levels in the case the principal energy level of the first charge transport layer 4a is attributable to a first charge transport material and the principal energy level of the second charge transport layer 4b is attributable to a second charge transport material are indicated as a typical case thereof.

Here, the organic photoelectric conversion element 30 of the third embodiment has the same layer structure as the organic photoelectric conversion element 10 of the first embodiment (see FIG. 1). The organic photoelectric conversion element 30 has the organic photoelectric conversion layer 3 provided between the negative electrode 1 and the positive electrode 2, the first charge transport layer 4a provided between the positive electrode 2 and the organic photoelectric conversion layer 3, and the second charge transport layer 4b provided between the negative electrode 1 and the organic photoelectric conversion layer 3. In the organic photoelectric conversion element 30 of the third embodiment, the first charge transport layer 4a has the electron trapping/scattering material 5 while the second charge transport layer 4b has the hole trapping/scattering material 6.

The first charge transport material and the second charge transport material have the same energy levels as in the first embodiment. Consequently, the first charge transport layer 4a and the second charge transport layer 4b are able to block the flow of dark current. In addition, the flow of electrons and holes generated in the organic photoelectric conversion layer is not impeded.

The first charge transport layer 4a has the electron trapping/scattering material 5. The electron trapping/scattering material 5 has a HOMO level which is +0.5 eV or more, or −0.5 eV or less, than the HOMO level of the first charge transport material (that is, the absolute value of the energy level difference E_{H1} is 0.5 eV or more). The electron trapping/scattering material 5 also has a LUMO level which is between −0.5 eV to +0.5 eV of the LUMO level of the first charge transport material (that is, the absolute value of the energy level difference E_{L1} is 0.5 eV or less). The HOMO level of the electron trapping/scattering material 5 is preferably at least 0.7 eV lower, and more preferably at least 1.0 eV lower than the HOMO level of the first charge transport material.

As a result of making the absolute value of the energy level difference E_{L1} between the LUMO level of the first charge transport material and the LUMO level of the electron trapping/scattering material 5 to be 0.5 eV or less, electrons unable to be completely blocked with the first charge transport material alone can be trapped or scattered within the first charge transport layer 4a. On the other hand, as a result of making the absolute value of the energy level difference E_{H1} between the HOMO level of the first charge transport material and the HOMO level of the electron trapping/scattering material 5 to be 0.5 eV or more, holes generated in the organic photoelectric conversion layer 3 are able to flow to the positive electrode 2 without being impeded. Consequently, dark current can be suppressed without lowering photoelectric conversion efficiency.

The second charge transport layer 4b has the hole trapping/scattering material 6. The hole trapping/scattering material 6 has a HOMO level which is between −0.5 eV to +0.5 eV of the HOMO level of the second charge transport material (that is, the absolute value of the energy level difference E_{H2} is 0.5 eV or less). The hole trapping/scattering material 6 also has a LUMO level that is +0.5 eV or more, or −0.5 eV or less, than the LUMO level of the second charge transport material (that is, the absolute value of the energy level difference E_{L2} is 0.5 eV or more). The LUMO level of the hole trapping/scattering material 6 is preferably at least 0.7 eV higher, and more preferably at least 1.0 eV higher than the LUMO level of the second charge transport material.

As a result of making the absolute value of the energy level difference E_{H2} between the HOMO level of the second charge transport material and the HOMO level of the hole trapping/scattering material 6 be 0.5 eV or less, holes unable to be completely blocked with the second charge transport material alone can be trapped or scattered within the second charge transport layer 4b. On the other hand, as a result of making the absolute value of the energy level difference E_{L2} between the LUMO level of the second charge transport material and the LUMO level of the hole trapping/scattering material 6 be 0.5 eV or more, electrons generated in the organic photoelectric conversion layer 3 are able to flow to the negative electrode 1 without being impeded. Consequently, dark current can be suppressed without lowering photoelectric conversion efficiency.

The first charge transport layer 4a has the same first charge transport material and the electron trapping/scattering material 5 as in the first embodiment. The second charge transport layer 4b has the same second charge transport material and hole trapping/scattering material 6 as in the second embodiment. Therefore, electrons and holes can be trapped and scattered. Thus, the generation of dark current can be suppressed and the flow of electrons and holes generated in the organic photoelectric conversion layer 3 is not impeded. Consequently, dark current can be suppressed without lowering photoelectric conversion efficiency.

A negative electrode 1, positive electrode 2 and organic photoelectric conversion layer 3 that are the same as those of the first embodiment or second embodiment can be respectively used for each of the negative electrode 1, the positive electrode 2 and the organic photoelectric conversion layer 3. The weight ratio of the electron trapping/scattering material 5 with respect to the first charge transport material and the weight ratio of the hole trapping/scattering material 6 with respect to the second charge transport material can be within the same ranges as in the first embodiment or second embodiment.

The organic photoelectric conversion element 30 can be fabricated using the same method as in the first embodiment and second embodiment.

### Fourth Embodiment

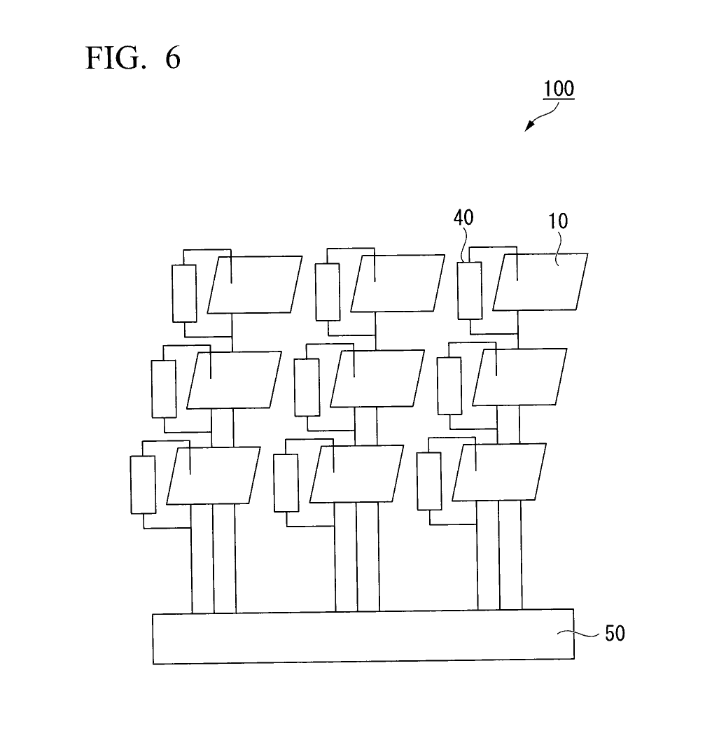

FIG. 6 is a drawing schematically showing an imaging device of a fourth embodiment.

An imaging device 100 of the fourth embodiment is provided with a plurality of organic photoelectric conversion elements 10, voltage application units 40 that apply a voltage to each of the organic photoelectric conversion elements 10, and a signal processing unit 50 that imports each of the photoelectrically converted signals of the organic photoelectric conversion elements 10. Although the organic photoelectric conversion element 10 of the first embodiment is used in FIG. 6, the fourth embodiment is not limited to this case. For example, the organic photoelectric conversion element 20 of the second embodiment or the organic photoelectric conversion element 30 of the third embodiment can also be used.

Although the organic photoelectric conversion elements 10 are arranged in three rows and three columns in FIG. 6, the fourth embodiment is not limited to this case, and a plurality of each of the organic photoelectric conversion elements 10 may be arranged at arbitrary locations without being in rows or columns. Although each voltage application unit 40 is connected to each organic photoelectric conversion element 10, voltage may also be applied simultaneously by connecting wires to each organic photoelectric conversion element 10 from a single voltage application unit.

The voltage application units 40 apply a voltage to the organic photoelectric conversion elements 10. If a reverse bias is applied to the organic photoelectric conversion elements 10 from the voltage application units 40, an electric field is generated in the organic photoelectric conversion elements 10. Electrons and holes generated in the organic photoelectric conversion layer 3 of each organic photoelectric conversion element 10 due this generated electric field are attracted to the negative electrode 1 and positive electrode 2, respectively, resulting in improvement of response speed. Since charge separability of excitons generated in the organic photoelectric conversion layer 3 due to this generated electric field improves, photoelectric conversion efficiency also improves.

There are no particular limitations on the voltage applied to the organic photoelectric conversion elements 10. Since a large applied voltage results in a correspondingly large electric field generated in the organic photoelectric conversion elements 10, photoelectric conversion efficiency and response speed improve. On the other hand, if the applied voltage is excessively large, current ends up flowing in a direction opposite from the target direction due to the yield phenomenon. More specifically, the applied voltage is preferably a voltage at which an electric field of 1.0×10⁴ V/cm to 1.0×10⁶ V/cm is generated in the organic photoelectric conversion layer.

Although the voltage application units 40 are provided for each organic photoelectric conversion element 10 in FIG. 6, the fourth embodiment is not limited to this case. A single power supply may be provided for the voltage application units 40, and wires may be connected so as to apply a voltage to each of the organic photoelectric conversion elements 10 from that power supply.

The signal processing unit 50 is connected to each of the organic photoelectric conversion elements 10. The signal processing unit 50 receives and processes signals that have been photoelectrically converted in the organic photoelectric conversion elements 10.

For example, if the organic photoelectric conversion elements 10 are arranged two-dimensionally in n rows and m columns, the intensity of light at each point of the organic photoelectric conversion elements 10 is sent to the signal processing unit 50 in the form of an electrical signal. The signal processing unit 50 is able to read the received electrical signals as image data by processing those signals. This type of imaging device 100 can be used as, for example, a video camera, digital still camera or general camera.

According to at least one of the previously explained embodiments, dark current can be suppressed without lowering photoelectric conversion efficiency by having an electron trapping/scattering material or hole trapping/scattering material.

### Examples

The following provides an explanation of Example 1.

The organic photoelectric conversion element of Example 1 has the same configuration as the organic photoelectric conversion element 30 of the third embodiment.

The specific material configuration of each layer of the organic photoelectric conversion element was set to: ITO/N,N′-dimethylquinacridone (first charge transport material) and B3PYMPM (electron trapping/scattering material) at a ratio of 6:4/N,N′-dimethylquinacridone and PDCDT at a ratio of 1:1 (organic photoelectric conversion layer)/PDCDT (second charge transport material) and mCP (hole trapping/scattering material) at a ratio of 6:4/Al.

Here, the HOMO level of B3PYMPM was about 1.3 eV lower than the HOMO level of N,N′-dimethylquinacridone, and the LUMO level of B3PYMPM was about 0.1 eV lower than the LUMO level of N,N′-dimethylquinacridone.

The HOMO level of mCP was about 0.1 eV higher than the HOMO level of PDCDT, and the LUMO level of mCP was about 1.4 eV higher than the LUMO level of PDCDT.

The organic photoelectric conversion element of Example 1 was fabricated under the conditions indicated below.

After solvent-washing of an ITO-coated glass substrate was performed, the substrate was further washed with UV/O₃. The N,N′-dimethylquinacridone and B3PYMPM were co-deposited on the substrate to a film thickness of 20 nm under reduced pressure of 10⁻⁴ Pa or lower. At this time, the N,N′-dimethylquinacridone and B3PYMPM were made to be at a weight ratio of 6:4 at room temperature.

Next, N,N′-dimethylquinacridone and a perylene-based compound in the form of PDCDT were co-deposited on this film obtained by depositing N,N′-dimethylquinacridone and B3PYMPM at a deposition rate of 1 Å/sec at room temperature to a film thickness of 40 nm. At this time, the N,N′-dimethylquinacridone and PDCDT were made to be at a weight ratio of 1:1.

Moreover, PDCDT and B3PYMPM were co-deposited on this N,N′-dimethylquinacridone and PDCDT at a reduced pressure of 10⁻⁴ Pa or lower to a film thickness of 20 nm. At this time, the PDCDT and mCP were made to be at a weight ratio of 6:4 at room temperature.

Al serving as a counter electrode was then vacuum-deposited at a thickness of 150 nm on these organic laminated films to produce an organic photoelectric conversion element. In the present example, the organic photoelectric conversion element was sealed by adhering a glass sealing substrate to the substrate with a UV-curable sealing material.

Electrical characteristics of this organic photoelectric conversion element were determined under conditions of applying a reverse bias voltage of −1 V using a pA meter/DC voltage source (4140B, Hewlett-Packard Co.). Cold light from a halogen light source (HL100E, Hoya-Shott Corp.) and a band-pass filter (MX0530, Asahi Spectra Co., Ltd.) were used for the light source. As a result, external quantum efficiency was 15.9% (irradiated wavelength: 530 nm) and dark current was 2.6×10⁻⁷ nA/cm².

The following provides an explanation of Comparative Example 1.

The organic photoelectric conversion element of Comparative Example 1 differs from the configuration of Example 1 in that the first charge transport layer and the second charge transport layer do not have the electron trapping/scattering material and hole trapping/scattering material, respectively. The remainder of the configuration was the same as that of Example 1.

The organic photoelectric conversion element of Comparative Example 1 has a configuration of: ITO/N,N′-dimethylquinacridone (first charge transport material)/N,N′-dimethylquinacridone and PDCDT at a ratio of 1:1 (organic photoelectric conversion layer)/PDCDT (second charge transport material)/Al.

The external quantum efficiency of the organic photoelectric conversion element of Comparative Example 1 was 13.1% (irradiated wavelength: 530 nm) and dark current was 1.1×10⁻⁶ nA/cm².

Dark current was reduced in Example 1 in comparison with Comparative Example 1. In addition, external quantum efficiency also improved. The organic photoelectric conversion element of Example 1 was determined to be able to suppress dark current without lowering photoelectric conversion efficiency by containing an electron trapping/scattering material and a hole trapping/scattering material.

The following provides an explanation of Example 2.

The specific material configuration of each layer of the organic photoelectric conversion element of Example 2 was set to: ITO/NPB (first charge transport material) and CBP (electron trapping/scattering material) at a ratio of 9:1/N,N-dimethylquinacridone and PDCDT at a ratio of 1:1 (organic photoelectric conversion layer)/Alq3 (second charge transport material) and TCTA (hole trapping/scattering material) at a ratio of 9:1/Al.

At this time, the HOMO level of CBP was about 0.6 eV lower than the HOMO level of NBP, and the LUMO level of CBP was about 0.2 eV lower than the LUMO level of NBP.

The HOMO level of TCTA was about 0.2 eV higher than the HOMO level of Alq3, and the LUMO level of TCTA was about 0.9 eV higher than the LUMO level of Alq3.

The materials used in the organic photoelectric conversion element of Example 2 differed from those of the organic photoelectric conversion element of Example 1 in that the first charge transport material and the second charge transport material were different. All other conditions were the same as those of the configuration of Example 1.

When external quantum efficiency and dark current were measured in the same manner as the organic photoelectric conversion element of Example 1, external quantum efficiency was 29.1% (irradiated wavelength: 530 nm) and dark current was 3.1×10⁻⁸ nA/cm².

The following provides an explanation of Comparative Example 2.

The organic photoelectric conversion element of Comparative Example 2 has the same configuration as Example 2 with the exception of the first charge transport layer and the second charge transport layer not having the electron trapping/scattering material and hole trapping/scattering material, respectively.

The specific material configuration of each layer was set to: ITO/NPB (first charge transport material)/N,N′-dimethylquinacridone and PDCDT at a ratio of 1:1 (organic photoelectric conversion layer)/Alq3 (second charge transport material)/Al. All other conditions were the same as those of the configuration of Example 2.

The external quantum efficiency of the organic photoelectric conversion element of Comparative Example 2 was 30.6% (irradiated wavelength: 530 nm) and dark current was 5.8×10⁻⁷ nA/cm².

Dark current was reduced in Example 2 in comparison with Comparative Example 2. In addition, at this time, external quantum efficiency also increased. The organic photoelectric conversion element of Example 2 was determined to be able to suppress dark current without lowering photoelectric conversion efficiency by containing an electron trapping/scattering material and a hole trapping/scattering material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An organic photoelectric conversion element comprising:
a positive electrode,
a negative electrode,
an organic photoelectric conversion layer provided between the positive electrode and the negative electrode,
a first charge transport layer provided between the positive electrode and the organic photoelectric conversion layer, and the first charge transport layer comprising a first charge transport material that has a LUMO level equal to or greater than the LUMO level of the organic photoelectric conversion layer, and
a second charge transport layer provided between the negative electrode and the organic photoelectric conversion layer, and the second charge transport layer comprising a second charge transport material that has a HOMO level equal to or less than the HOMO level of the organic photoelectric conversion layer, wherein,
the first charge transport layer further contains an electron trapping/scattering material, wherein
the electron trapping/scattering material has a HOMO level which is +0.5 eV or more, or −0.5 eV or less, than the HOMO level of the first charge transport material, and has a LUMO level which is between −0.5 eV to +0.5 eV of the LUMO level of the first electron transport material.

2. An organic photoelectric conversion element comprising:
a positive electrode,
a negative electrode,
an organic photoelectric conversion layer provided between the positive electrode and the negative electrode,
a first charge transport layer provided between the positive electrode and the organic photoelectric conversion layer, and the first charge transport layer comprising a first charge transport material that has a LUMO level equal to or greater than the LUMO level of the organic photoelectric conversion layer, and
a second charge transport layer provided between the negative electrode and the organic photoelectric conversion layer, and the second charge transport layer comprising a second charge transport material which has a HOMO level equal to or less than a HOMO level of the organic photoelectric conversion layer, wherein,
the second charge transport layer further contains a hole trapping/scattering material, wherein,
the hole trapping/scattering material has a HOMO level which is between −0.5 eV to +0.5 eV of the HOMO level of the second charge transport material, and has a LUMO level which is +0.5 eV or more, or −0.5 eV or less, than the LUMO level of the second electron transport material.

3. The organic photoelectric conversion element according to claim 1, wherein the second charge transport layer further contains an electron trapping/scattering material, the hole trapping/scattering material has a HOMO level which is between −0.5 eV to +0.5 eV of the HOMO level of the second charge transport material, and has a LUMO level which is +0.5 eV or more, or −0.5 eV or less, than the LUMO level of the second charge transport material.

4. The organic photoelectric conversion element according to claim 1, wherein the electron trapping/scattering material is contained in the first charge transport layer at a weight ratio of 1% to 50%.

5. The organic photoelectric conversion element according to claim 3, wherein the electron trapping/scattering material is contained in the first charge transport layer at a weight ratio of 1% to 50%.

6. The organic photoelectric conversion element according to claim 2, wherein the hole trapping/scattering material is contained in the second charge transport layer at a weight ratio of 1% to 50%.

7. The organic photoelectric conversion element according to claim 3, wherein the hole trapping/scattering material is contained in the second charge transport layer at a weight ratio of 1% to 50%.

8. The organic photoelectric conversion element according to claim 1, wherein the energy level of the positive electrode is at least 1.3 eV lower than the LUMO level of the first charge transport material.

9. The organic photoelectric conversion element according to claim 2, wherein the energy level of the positive electrode is at least 1.3 eV lower than the LUMO level of the first charge transport material.

10. The organic photoelectric conversion element according to claim 1, wherein the energy level of the negative electrode is at least 1.3 eV higher than the HOMO level of the second charge transport material.

11. The organic photoelectric conversion element according to claim 2, wherein the energy level of the negative electrode is at least 1.3 eV higher than the HOMO level of the second charge transport material.

12. The organic photoelectric conversion element according to claim 1, wherein the LUMO level of the first charge transport material is higher than the LUMO level of the organic photoelectric conversion layer.

13. The organic photoelectric conversion element according to claim 2, wherein the LUMO level of the first charge transport material is higher than the LUMO level of the organic photoelectric conversion layer.

14. The organic photoelectric conversion element according to claim 1, wherein the HOMO level of the second charge transport material is lower than the HOMO level of the organic photoelectric conversion layer.

15. The organic photoelectric conversion element according to claim 2, wherein the HOMO level of the second charge transport material is lower than the HOMO level of the organic photoelectric conversion layer.

16. An imaging device comprising the organic photoelectric conversion element according to claim 1, wherein the photoelectric conversion element is included as photoelectric conversion elements, voltage application units that apply a voltage to each of the organic photoelectric conversion elements, and a signal processing unit that reads each of photoelectrically converted signals of the organic photoelectric conversion elements.

17. An imaging device comprising the organic photoelectric conversion element according to claim 2, wherein the photoelectric conversion element is included as photoelectric conversion elements, voltage application units that apply a voltage to each of the organic photoelectric conversion elements, and a signal processing unit that reads each of photoelectrically converted signals of the organic photoelectric conversion elements.
